(19) United States
(12) Patent Application Publication
(10) Pub. No.: US 2025/0133753 A1
(43) Pub. Date: Apr. 24, 2025

(54) STRUCTURE AND FORMATION METHOD OF PACKAGE WITH INTEGRATED CHIPS AND CAPACITOR

(71) Applicant: Taiwan Semiconductor Manufacturing Company, Ltd., Hsinchu (TW)

(72) Inventor: Wen-Shiang LIAO, Miaoli County (TW)

(73) Assignee: Taiwan Semiconductor Manufacturing Company, Ltd., Hsinchu (TW)

(21) Appl. No.: 18/491,576

(22) Filed: Oct. 20, 2023

(51) Int. Cl. H01L 23/00; H01L 23/31; H01L 25/16

(52) U.S. Cl. CPC H10D 1/042; H01L 23/3107; H01L 24/08; H01L 24/80; H01L 25/16; H10D 1/716; H01L 24/05; H01L 24/13; H01L 2224/0401; H01L 2224/08145; H01L 2224/13017; H01L 2224/80895; H01L 2224/80896

(57) ABSTRACT

A package structure and a formation method are provided. The method includes receiving a first chip structure, and the first chip structure has multiple conductive bonding structures and a dielectric bonding structure surrounding the conductive bonding structures. Top surfaces of the conductive bonding structures and the dielectric bonding structure are coplanar. The method also includes bonding a second chip structure to the dielectric bonding structure and the conductive bonding structures through dielectric-to-dielectric bonding and metal-to-metal bonding. The method further includes forming an insulating layer over the first chip structure, and the insulating layer laterally surrounds the first chip structure. In addition, the method includes forming a capacitor element laterally spaced apart from the second chip structure, and the insulating layer partially surrounds the capacitor element.

### BACKGROUND

The semiconductor integrated circuit (IC) industry has experienced rapid growth. Continuing advances in semiconductor manufacturing processes have resulted in semiconductor devices with finer features and/or higher degrees of integration. Functional density (i.e., the number of interconnected devices per chip area) has generally increased while feature sizes (i.e., the smallest component that can be created using a fabrication process) have decreased. This scaling-down process generally provides benefits by increasing production efficiency and lowering associated costs.

A chip package not only provides protection for semiconductor devices from environmental contaminants, but also provides a connection interface for the semiconductor devices packaged therein. Smaller package structures, which take up less space or are lower in height, have been developed to package the semiconductor devices.

New packaging technologies have been developed to further improve the density and functionality of semiconductor dies. These relatively new types of packaging technologies for semiconductor dies face manufacturing challenges.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1E are cross-sectional views of various stages of a process for forming a portion of a package structure, in accordance with some embodiments.

FIG. 2 is a cross-sectional view of a portion of a package structure, in accordance with some embodiments.

FIG. 3 is a cross-sectional view of a portion of a package structure, in accordance with some embodiments.

FIG. 4 is a cross-sectional view of a portion of a package structure, in accordance with some embodiments.

FIG. 5 is a cross-sectional view of a portion of a package structure, in accordance with some embodiments.

FIGS. 6A-6J are cross-sectional views each showing a portion of a capacitor element of a package structure, in accordance with some embodiments.

FIG. 7 is a plan view of a portion of a package structure, in accordance with some embodiments.

FIG. 8 is a cross-sectional view of a portion of a package structure, in accordance with some embodiments.

FIG. 9 is a cross-sectional view of a portion of a package structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

Embodiments of the disclosure may relate to package structures such as three-dimensional (3D) packaging, 3D-IC devices, and 2.5D packaging. Embodiments of the disclosure form a package structure including a substrate that carries one or more dies or packages and a protective element (such as a protective lid) aside the dies or packages. The protective element may also function as a warpage-control element and/or heat dissipation element.

Other features and processes may also be included. For example, testing structures may be included to aid in the verification testing of the 3D packaging, 3DIC devices, and/or 2.5 D packaging. The testing structures may include, for example, test pads formed in a redistribution layer or on a substrate that allows testing to be conducted using probes or probe cards and the like. Verification testing may be performed on intermediate structures as well as the final structure. Additionally, the structures and methods disclosed herein may be used in conjunction with testing methodologies that incorporate intermediate verification of known good dies to increase the yield and decrease costs.

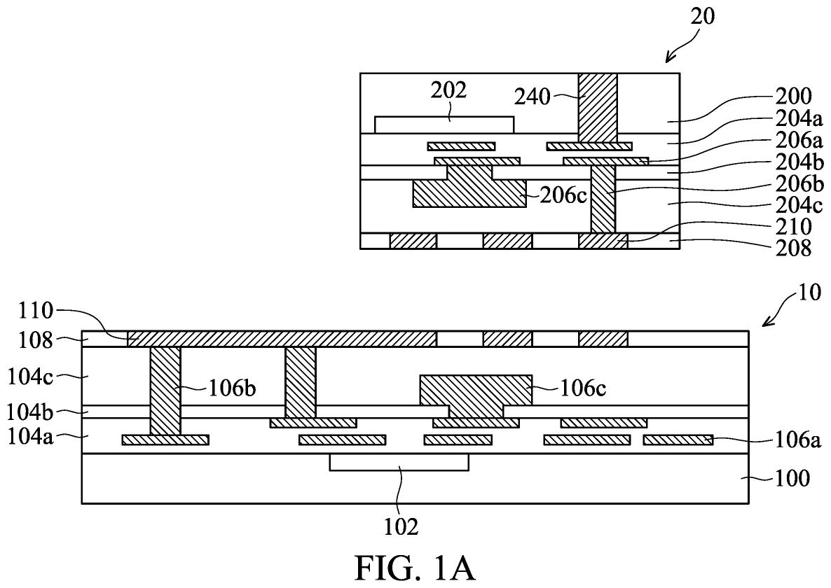

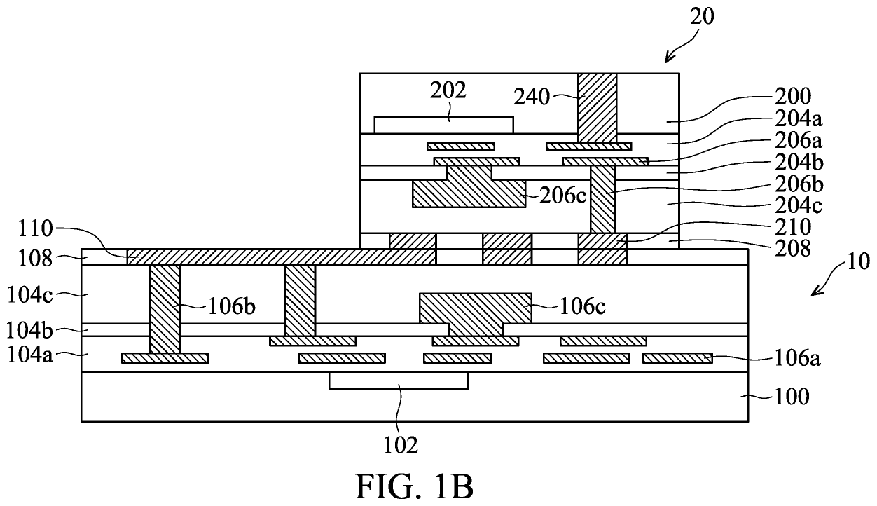

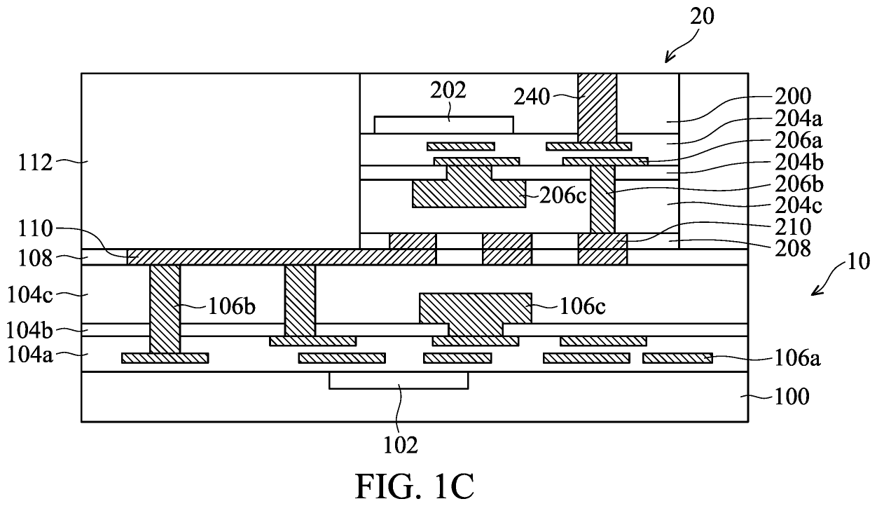

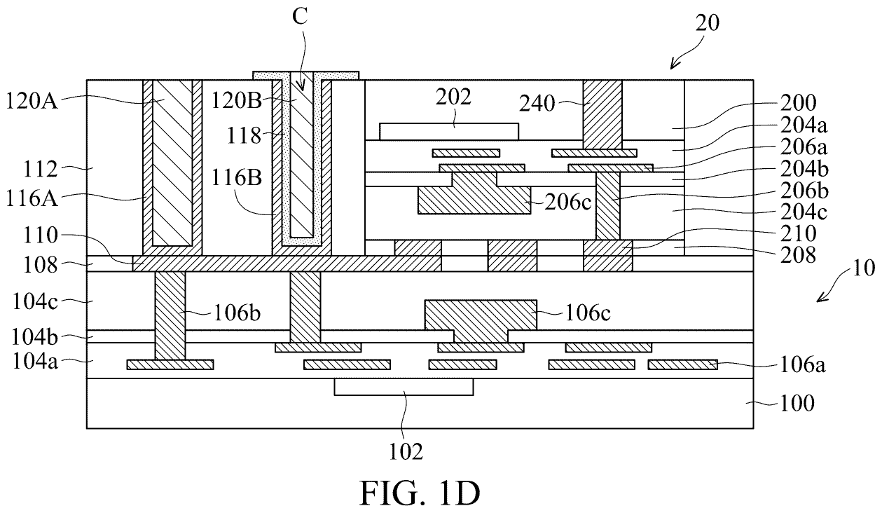

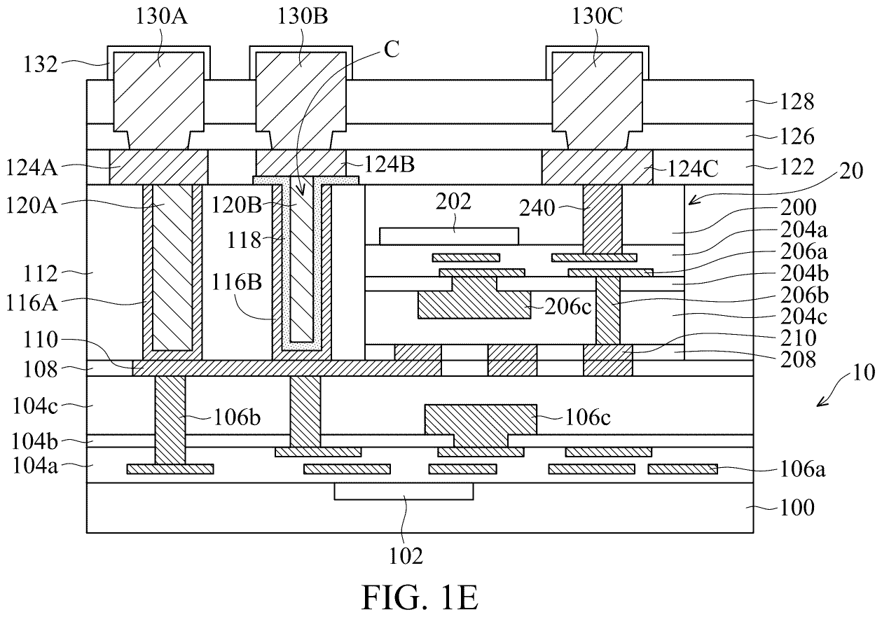

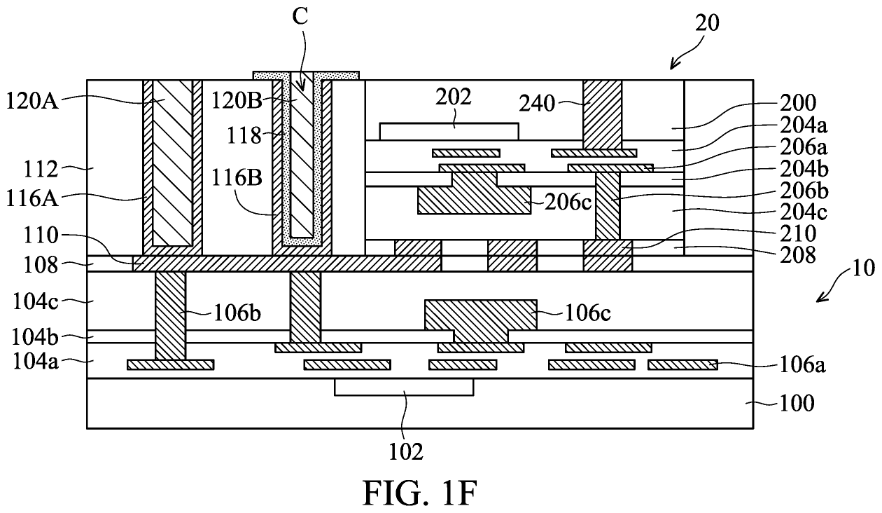

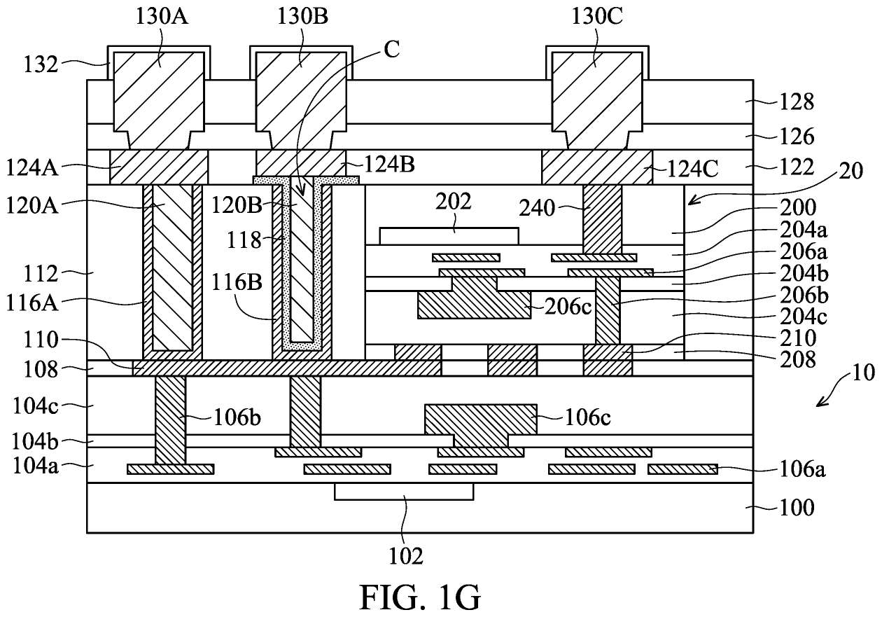

FIGS. 1A-1E are cross-sectional views of various stages of a process for forming a package structure, in accordance with some embodiments. As shown in FIG. 1A, a chip structure (or a chip-containing structure) 10 is received, in accordance with some embodiments. In some embodiments, the chip structure 10 is a semiconductor wafer that includes multiple semiconductor chips. After a subsequent sawing process, multiple semiconductor chips that are separated from each other may be obtained. In some other embodiments, the chip structure 10 is a single semiconductor chip.

In some embodiments, the chip structure 10 includes a semiconductor substrate 100. In some embodiments, the semiconductor substrate 100 is a bulk semiconductor substrate, such as a semiconductor wafer. The semiconductor substrate 100 may include silicon or another elementary semiconductor material such as germanium. The semiconductor substrate 100 may be un-doped or doped (e.g., p-type, n-type, or a combination thereof). In some embodiments, the semiconductor substrate 100 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate 100 includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate 100 is an active layer of a semiconductor-on-insulator (SOI) substrate. The SOI substrate may be fabricated using a separation by implantation of oxygen (SIMOX) process, a wafer bonding process, another applicable method, or a combination thereof. In some other embodiments, the semiconductor substrate 100 includes a multi-layered structure. For example, the semiconductor substrate 100 includes a silicon-germanium layer formed on a bulk silicon layer.

Various device elements 102 are formed in or over the semiconductor substrate 100. One of the device elements 102 is shown in FIG. 1A. Examples of the various device elements 102 include transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.), diodes, or another suitable element. In some embodiments, the device element 102 shown in FIG. 1A includes a baseband device, a logic device, or another suitable device. Various processes may be used to form the various device elements, including deposition, etching, implantation, photolithography, annealing, and other suitable processes.

The chip structure 10 may include a front-side interconnection structure. In some embodiments, the front-side interconnection structure includes multiple dielectric structures 104a, 104b, and 104c and multiple conductive features 106a, 106b, and 106c surrounded by the dielectric structures 104a-104c. Each of the dielectric structures 104a-104c may include one or more dielectric layers. The conductive features 106a-106c may include conductive lines, conductive pads, conductive contacts, and conductive vias. In some embodiments, the conductive feature 106c is a conductive pad connected to a top metal of the conductive lines. In some embodiments, the conductive features 106b are conductive vias that penetrate through multiple dielectric layers.

The dielectric layers of the dielectric structures 104a-104c may be made of or include silicon oxide, silicon oxynitride, silicon nitride, carbon-containing silicon oxide, carbon-containing silicon nitride, carbon-containing silicon oxynitride, another suitable materials, or a combination thereof. The conductive features 106a-106c may be made of or include copper, tungsten, cobalt, aluminum, tantalum, gold, another suitable material, or a combination thereof. The formation of the front-side interconnection structure may involve multiple deposition processes, patterning processes, planarization processes, another applicable process, or a combination thereof.

The device elements of the chip structure 10 are interconnected by the front-side interconnection structure to form integrated circuit devices, such as logic devices, memory devices (e.g., static random access memory, SRAM), radio frequency (RF) devices, input/output (I/O) devices, a system-on-chip (SoC) device, one or more other types of devices, or a combination thereof.

As shown in FIG. 1A, the chip structure 10 also includes multiple conductive bonding structures 110 and a dielectric bonding structure 108, in accordance with some embodiments. The dielectric bonding structure 108 laterally surrounds the conductive bonding structures 110. The dielectric bonding structure 108 may be made of or include silicon oxide, carbon-containing silicon oxide, silicon oxynitride, another suitable material, or a combination thereof. The dielectric bonding structure 108 may be deposited over the front-side interconnection structure using a chemical vapor deposition (CVD) process or the like.

Afterwards, the conductive bonding structures 110 are formed in the dielectric bonding structure 108, as shown in FIG. 1A in accordance with some embodiments. In some embodiments, some of the conductive bonding structures 110 are electrically connected to the conductive features 106b thereunder. In some embodiments, the conductive bonding structure 110 and the conductive feature 106b thereunder are two linked portions of a single conductive structure that is formed in the same process.

In some embodiments, the top surfaces of the dielectric bonding structure 108 and the conductive bonding structures 110 are coplanar, as shown in FIG. 1A. In some embodiments, the formation of the conductive bonding structures 110 involves one or more planarization processes, so as to ensure that top surfaces of the dielectric bonding structure 108 and the conductive bonding structures 110 are coplanar. For example, a chemical mechanical polishing (CMP) process is used.

As shown in FIG. 1A, a chip structure (or a chip-containing structure) 20 is picked up and ready to be bonded to the chip structure 10, in accordance with some embodiments. In some embodiments, the chip structure 10 is wider than the chip structure 20. In some embodiments, the chip structure 20 is a single semiconductor chip. In some embodiments, the chip structure 20 is a tested known good die.

In some embodiments, similar to the chip structure 10, the chip structure 20 includes a semiconductor substrate 200. In some embodiments, the semiconductor substrate 200 is a bulk semiconductor substrate. The semiconductor substrate 200 may include silicon or another elementary semiconductor material such as germanium. The semiconductor substrate 200 may be un-doped or doped (e.g., p-type, n-type, or a combination thereof). In some embodiments, the semiconductor substrate 200 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate 200 includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate 200 is an active layer of a semiconductor-on-insulator (SOI) substrate. The SOI substrate may be fabricated using a separation by implantation of oxygen (SIMOX) process, a wafer bonding process, another applicable method, or a combination thereof. In some other embodiments, the semiconductor substrate 200 includes a multi-layered structure. For example, the semiconductor substrate 200 includes a silicon-germanium layer formed on a bulk silicon layer.

Various device elements 202 are formed in or over the semiconductor substrate 200. One of the device elements 202 is shown in FIG. 1A. Examples of the various device elements 202 include transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.), diodes, or another suitable element. In some embodiments, the device element 202 shown in FIG. 1A includes an RF device, an analog device, or another suitable device. Various processes may be used to form the various device elements, including deposition, etching, implantation, photolithography, annealing, and other suitable processes.

The chip structure 20 may include a front-side interconnection structure. In some embodiments, the front-side interconnection structure includes multiple dielectric structures 204a, 204b, and 204c and multiple conductive features 206a, 206b, and 206c surrounded by the dielectric structures 204a-204c. Each of the dielectric structures 204a-204c may include one or more dielectric layers. The conductive features 206a-206c may include conductive lines, conductive pads, conductive contacts, and conductive vias. In some embodiments, the conductive feature 206c is a conductive pad connected to a top metal of the conductive lines. In some embodiments, the conductive features 206b are conductive vias that penetrate through multiple dielectric layers.

The dielectric layers of the dielectric structures 204a-204c may be made of or include silicon oxide, silicon oxynitride, silicon nitride, carbon-containing silicon oxide, carbon-containing silicon nitride, carbon-containing silicon oxynitride, another suitable materials, or a combination thereof. The conductive features 206a-206c may be made of or include copper, tungsten, cobalt, aluminum, tantalum, gold, another suitable material, or a combination thereof. The formation of the front-side interconnection structure may involve multiple deposition processes, patterning processes, planarization processes, another applicable process, or a combination thereof.

The device elements of the chip structure 20 are interconnected by the front-side interconnection structure to form integrated circuit devices, such as analog devices, memory devices (e.g., static random access memory, SRAM), radio frequency (RF) devices, input/output (I/O) devices, a system-on-chip (SoC) device, logic devices, one or more other types of devices, or a combination thereof.

In some embodiments, the chip structure 20 includes multiple through-chip vias 240 extending into the semiconductor substrate 200. As shown in FIG. 1A, one of the through-chip vias 240 is shown. Each of the through-chip vias 240 may be electrically connected to one or more of the conductive features 206a formed in the front-side interconnection structure. In some embodiments, an insulating layer is formed between the semiconductor substrate 200 and the through-chip vias 240, so as to prevent short circuiting between the through-chip vias 240 and the semiconductor substrate 200. The insulating layer may be made of or include silicon oxide, silicon oxynitride, silicon nitride, another suitable material, or a combination thereof. In some embodiments, the through-chip via 240 penetrates through the semiconductor substrate 200. In some other embodiments, the through-chip via 240 extends into the semiconductor substrate 200 without completely penetrating through the semiconductor substrate 200.

As shown in FIG. 1A, the chip structure 20 also includes multiple conductive bonding structures 210 and a dielectric bonding structure 208, in accordance with some embodiments. The dielectric bonding structure 208 laterally surrounds the conductive bonding structures 210. The dielectric bonding structure 208 may be made of or include silicon oxide, carbon-containing silicon oxide, silicon oxynitride, another suitable material, or a combination thereof. The dielectric bonding structure 208 may be deposited over the front-side interconnection structure using a chemical vapor deposition (CVD) process or the like.

Afterwards, the conductive bonding structures 210 are formed in the dielectric bonding structure 208, as shown in FIG. 1A in accordance with some embodiments. In some embodiments, some of the conductive bonding structures 210 are electrically connected to the conductive features 206b thereunder. In some embodiments, the conductive bonding structure 210 and the conductive feature 206b thereunder are two linked portions of a single conductive structure that is formed in the same process.

In some embodiments, the top surfaces of the dielectric bonding structure 208 and the conductive bonding structures 210 are coplanar, as shown in FIG. 1A. In some embodiments, the formation of the conductive bonding structures 210 involves one or more planarization processes, so as to ensure that top surfaces of the dielectric bonding structure 208 and the conductive bonding structures 210 are coplanar. For example, a chemical mechanical polishing (CMP) process is used.

As shown in FIG. 1B, the chip structures 10 and 20 are bonded together through direct bonding, in accordance with some embodiments. The direct bonding may be a hybrid bonding that includes dielectric-to-dielectric bonding and metal-to-metal bonding. In some embodiments, there is no tin-containing solder elements or solder bump formed between the chip structures 10 and 20. In some embodiments, the bonding between the chip structures 10 and 20 is a bumpless thermos-compression hybrid bonding.

In some embodiments, the chip structure 20 is picked and placed directly on the dielectric bonding structure 108 and the conductive bonding structures 110. As a result, the dielectric bonding structure 108 of the chip structure 10 is in direct contact with the dielectric bonding structure 208 of the chip structure 20. The conductive bonding structures 110 of the chip structure 10 are in direct contact with the conductive bonding structures 210 of the chip structure 20.

Before the placing of the chip structure 20, planarization processes are performed, so as to provide highly planarized bonding surfaces. In some embodiments, there is no gap between the dielectric bonding structure 108 and the dielectric bonding structure 208. In some embodiments, there is no gap between the conductive bonding structures 110 and 210. In some embodiments, a thermal operation is then used to enhance the bonding between the conductive bonding structures 110 and 210. The temperature of the thermal operation may within a range from about 100 degrees C. to about 500 degrees C. In some embodiments, a thermos-compression process is used to enhance the bonding between the chip structures 10 and 20. The thermos-compression process may be performed at a temperature around 400 degrees C. for about 2 hours.

As shown in FIG. 1C, an insulating layer 112 is formed over the chip structure 10 to laterally surround the chip structure 20, in accordance with some embodiments. In some embodiments, the top surface of the insulating layer 112 is coplanar with the surfaces of the semiconductor substrate 200 and the through-chip via 240, as shown in FIG. 1C. The insulating layer 112 may be made of or include silicon oxide, silicon oxynitride, silicon nitride, carbon-containing silicon oxide, carbon-containing silicon oxynitride, carbon-containing silicon nitride, another suitable material, or a combination thereof. In some embodiments, the insulating layer 112 is not made of a molding compound material or an epoxy-based resin material.

In some embodiments, an insulating material layer used for forming the insulating layer 112 is deposited over the chip structures 10 and 20. The insulating material layer may be deposited using a CVD process, an atomic layer deposition (ALD) process, a flowable chemical vapor deposition (FCVD) process, a spin-coating process, another applicable process, or a combination thereof. Afterwards, a planarization process is used to partially remove the insulating material layer. The planarization process may be performed until the through-chip via 240 is exposed. In some embodiments, the semiconductor substrate 200 and/or the through-chip via 240 are partially removed during the planarization process. As a result, the remaining portion of the insulating material layer forms the insulating layer 112. The planarization process may include a CMP process, a grinding process, an etching process, a dry polishing process, another applicable process, or a combination thereof.

The insulating layer 112 is partially removed to form openings, in accordance with some embodiments. The openings may expose one or more of the conductive bonding structures 110 thereunder. The openings may have various cross-sectional shapes. Each of the openings may have a circular cross-sectional shape, a rectangular cross-sectional shape, a square cross-sectional shape, an oval cross-sectional shape, or another suitable cross-sectional shape. Each of the openings may have a width that is within a range from about 0.05 μm to about 0.5 μm.

Afterwards, conductive layers 116A and 116B are respectively formed along the bottom and sidewalls of the left opening and the right opening, as shown in FIG. 1D in accordance with some embodiments. The conductive layers 116A and 116B may be made of or include copper, cobalt, gold, another suitable material, or a combination thereof. In some embodiments, each of the conductive layers 116A and 116B is electrically connected to the same conductive bonding structures 110 thereunder. In these cases, the conductive layers 116A and 116B are electrically connected to each other. In some embodiments, the conductive layers 116A and 116B are electrically connected to one of the conductive bonding structures 208 of the chip structure 20 through the conductive bonding structures 110 thereunder.

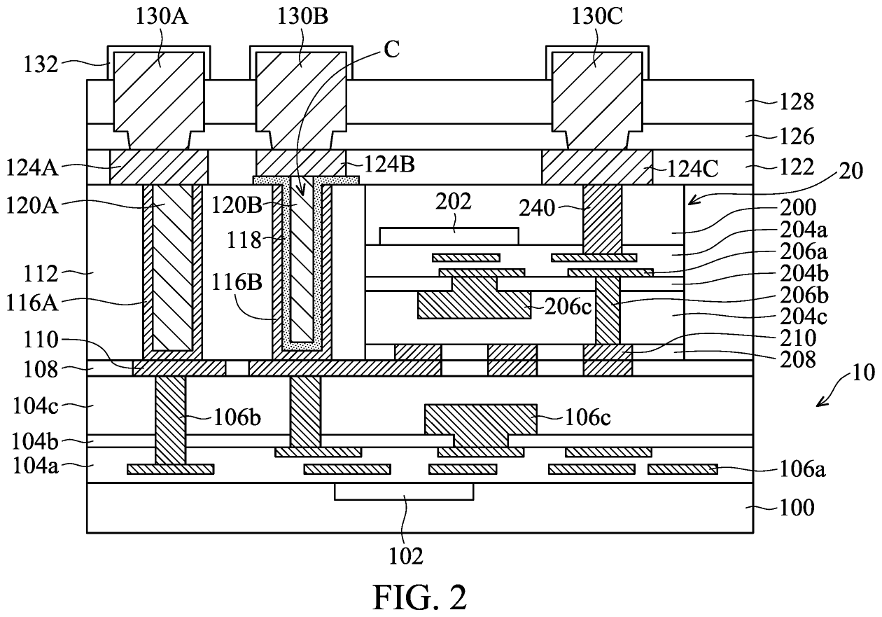

However, embodiments of the disclosure are not limited thereto. Many variations and/or modifications can be made to embodiments of the disclosure. In some other embodiments (such as that shown in FIG. 2), the conductive layers 116A and 116B are electrically connected to different conductive bonding structures 110 thereunder. Thus, the conductive layers 116A and 116B are not electrically connected to each other.

In some embodiments, the conductive layers 116A and 116B are formed using an electrochemical plating (ECP) process. A patterned seed layer may be formed over the bottoms and sidewalls of the openings.

One or more ECP processes are then performed to plate a conductive material on the patterned seed layer. As a result, the patterned seed layer and the plated conductive material together form the conductive layers 116A and 116B. In some embodiments, the conductive layers 116A and 116B are formed simultaneously.

As shown in FIG. 1D, a capacitor dielectric layer 118 is formed over the conductive layer 116B, in accordance with some embodiments. In some embodiments, a portion of the capacitor dielectric layer 118 extends over the top surfaces of the conductive layer 116B and the insulating layer 112. The capacitor dielectric layer 118 may be made of a high dielectric constant material. The capacitor dielectric layer 118 may be made of or include hafnium zirconium oxide, zirconium oxide, aluminum oxide, hafnium oxide, hafnium silicon oxide, zirconium titanium oxide, titanium oxide, tantalum oxide, strontium titanium oxide, barium titanium oxide, barium strontium titanium oxide, lead zirconium titanium oxide, silicon nitride, another suitable material, or a combination thereof.

A capacitor dielectric material layer may be deposited over the conductive layer 116B using a CVD process, an ALD process, a low-temperature plasma enhanced chemical vapor deposition process, a physical vapor deposition (PVD) process, a spin-coating process, another applicable process, or a combination thereof. The deposition temperature of the capacitor dielectric material layer may be within a range from about 150 degrees C. to about 400 degrees C. In some other embodiments, the deposition temperature of the capacitor dielectric material layer is within a range from about 180 degrees C. to about 250 degrees C. Afterwards, one or more photolithography processes and one or more etching processes are used to partially remove the capacitor dielectric material layer. As a result, the remaining portion of the capacitor dielectric material layer forms the capacitor dielectric layer 118, as shown in FIG. 1D.

Many variations and/or modifications can be made to embodiments of the disclosure. In some other embodiments, the capacitor dielectric layer 118 is formed using liquid-phase material. For example, a liquid-phase oxide material (such as liquid-phase silicon oxide and spin-on glass) and/or a liquid-phase polymer material (such as polyimide and polybenzoxazoles) may be used to form the capacitor dielectric layer 118. In some embodiments, a thermal curing operation is used to harden the liquid-phase material into the capacitor dielectric layer 118.

In some embodiments, the capacitor dielectric layer 118 is a single layer. In some other embodiments, the capacitor dielectric layer 118 includes multiple sub-layers. In some embodiments, some of the sub-layers are made of different materials. In some other embodiments, the sub-layers are made of the same material. In some embodiments, the capacitor dielectric layer 118 includes an aluminum oxide sub-layer and two zirconium oxide sub-layers. The aluminum oxide sub-layer may be sandwiched between the zirconium oxide sub-layers.

As shown in FIG. 1D, conductive layers 120A and 120B are respectively formed over the conductive layer 116A and the capacitor dielectric layer 118, in accordance with some embodiments. In some embodiments, the conductive layers 120A and 120B fill the remaining space of the openings. In some embodiments, the top surfaces of the conductive layer 120A and the insulating layer 112 are substantially coplanar. In some embodiments, the top surfaces of the conductive layer 120B and the capacitor dielectric layer 118 are substantially coplanar.

The material of the conductive layers 120A and 120B may be the same as or similar to that of the conductive layers 116A and 116B. In some embodiments, a conductive material layer is deposited. In some embodiments, the conductive material layer is deposited using an ECP process. A seed layer may be deposited over the conductive layer 116 and the capacitor dielectric layer 118, so as to assist in the formation of the conductive material layer. In some embodiments, the conductive layers 120A and 120B are formed simultaneously.

In some embodiments, the conductive layer 116B, the capacitor dielectric layer 118, and the conductive layer 120B together forms a capacitor element C. The capacitor element C may be a decoupling capacitor. The capacitor element C is laterally spaced apart from the chip structure 20, as shown in FIG. 1D. The capacitor element C may help to reduce the signal noise during the operation of the chip structures 20 and/or 10. In some embodiments, the insulating layer 112 laterally surrounds the lower portion of the capacitor element C. In some embodiments, upper portions of the capacitor dielectric layer 118 and the conductive layer 120B protrude from the top surface of the insulating layer 112, as shown in FIG. 1D. In some embodiments, the bottommost surface of the capacitor dielectric layer 118 is positioned between the top surface and the bottom surface of the insulating layer 112.

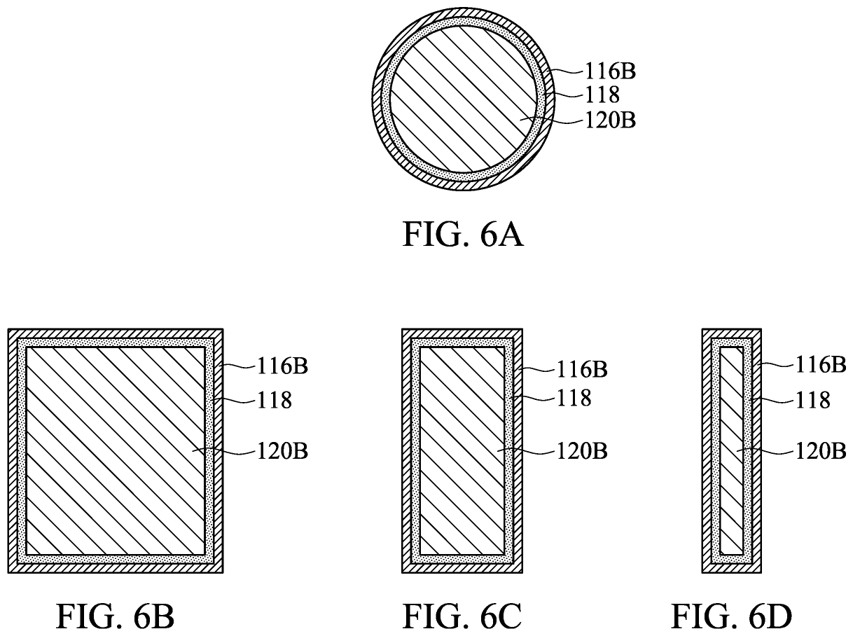

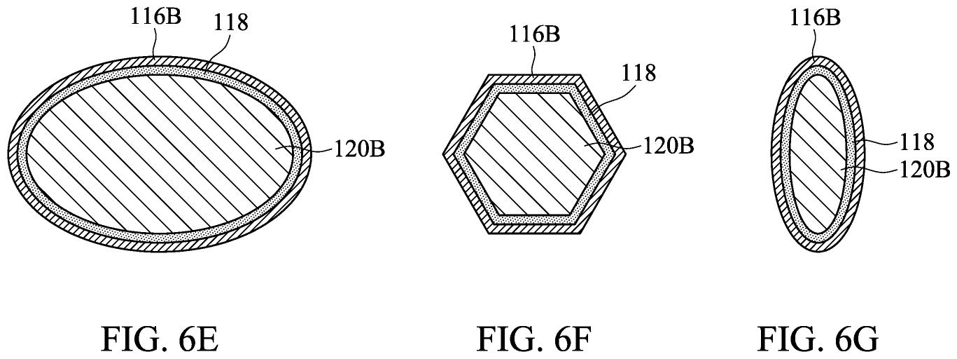

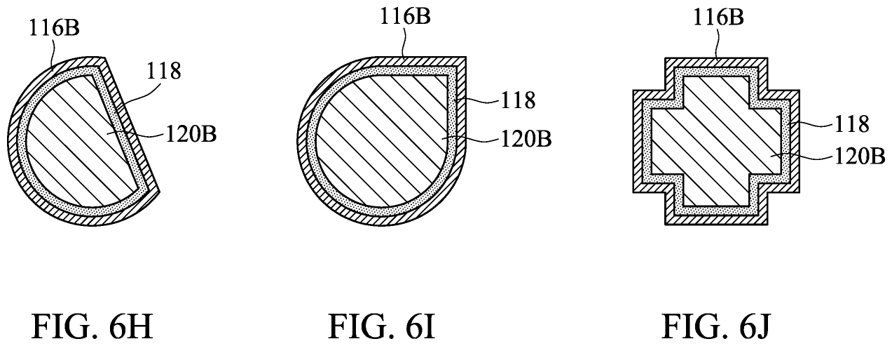

FIGS. 6A-6J are cross-sectional views each showing a portion of a capacitor element of a package structure, in accordance with some embodiments. The capacitor element C may be formed to have one of the cross-sectional views shown in FIGS. 6A-6J. By fine-tuning the size, profile, and/or shape of the capacitor elements, the capacitance of the capacitor element C may be tuned accordingly. The capacitance may be tuned within a range from about 100 fF to about 500 nF, which is suitable for various applications.

As shown in FIG. 1E, a dielectric layer 122 is deposited over the structure shown in FIG. 1D, in accordance with some embodiments. The material and formation method of the dielectric layer 122 may be the same as or similar to those of the dielectric structure 104c. Afterwards, the dielectric layer 122 is patterned to form openings that expose conductive features thereunder. For example, the conductive layers 116A and 120A, the conductive layer 120B of the capacitor element C, and the through-chip via 240 are exposed.

Afterwards, conductive features 124A, 124B, and 124C are formed in the openings of the dielectric layer 122 to form electrical connection to the conductive features thereunder, as shown in FIG. 1E in accordance with some embodiments. The material and formation method of the conductive features 124A, 124B, and 124C may be the same as or similar to those of the conductive layers 120A and 120B.

As shown in FIG. 1E, a patterned passivation layer 126 is then formed over the dielectric layer 122 and the conductive features 124A-124C, in accordance with some embodiments. The patterned passivation layer 126 has multiple openings that expose the conductive features 124A-124C. The patterned passivation layer 126 may be made of or include silicon nitride, silicon oxynitride, another suitable material, or a combination thereof. The formation of the patterned passivation layer 126 may involve one or more deposition processes and one or more patterning processes.

Afterwards, conductive features 130A, 130B, and 130C are respectively formed over the conductive features 124A-124C, as shown in FIG. 1E in accordance with some embodiments. The conductive features 130A, 130B, and 130C may function as conductive pads. The conductive features 130A, 130B, and 130C may be made of or include copper, aluminum, cobalt, another suitable material, or a combination thereof.

A protective layer 128 may then be formed over the passivation layer 126 to laterally surround the lower portions of the conductive features 130A-130C, as shown in FIG. 1E. The protective layer 128 may be made of or include a polymer material. The polymer material may be made of or include polybenzoxazole (PBO), polyimide, epoxy-based resin, another suitable polymer material, or a combination thereof. In some other embodiments, the protective layer 128 is made of or include silicon nitride, silicon oxide, silicon oxynitride, silicon carbide, another suitable dielectric material, or a combination thereof. The protective layer 128 may be formed using a spin-coating process, a CVD process, another applicable process, or a combination thereof.

Afterwards, under bump metallization (UBM) structures 132 are formed over the conductive features 130A-130C, as shown in FIG. 1E in accordance with some embodiments. The UBM structures 132 may be used to receive and hold tin-containing solder bumps. The UBM structures 132 may be made of or include nickel, palladium, gold, another suitable material, or a combination thereof. The UBM structures 132 may be formed using an electroplating process, an electro-chemical plating process, an immersion process, another applicable process, or a combination thereof.

Afterwards, in some embodiments, a sawing process is used to separate the structure into multiple package structures. One of the package structures is shown in FIG. 1E. In some embodiments, the chip structure 10 is originally a semiconductor wafer. After the sawing process, the chip structure 10 shown in FIG. 1E may be a single semiconductor chip. In some embodiments, the outermost edge of the insulating layer 112 is coplanar with the outermost edge of the chip structure 10. The package structure shown in FIG. 1E may function as a system on integrated chips (SoIC) that may further be integrated into a chip on wafer on substrate (CoWoS) package structure, an integrated fan-out (InFO) package structure, or the like. Since the capacitor element C is formed within the SoIC package structure, the interconnection length between the capacitor element C and the chip structures is very short, which allows for a faster operation speed.

As shown in FIG. 1E, the chip structure 10 extends across the opposite edges of the chip structure 20 and the opposite edges of the capacitor element C constructed by the capacitor dielectric layer 118 and the conductive layers 116B and 120B. In some embodiments, the conductive layer 120B is used as an electrode of the capacitor element C and is electrically connected to the conductive feature 130B, as shown in FIG. 1E. In some embodiments, the conductive feature 130B is used to provide electrical connection to ground. In some embodiments, the conductive layer 116B is used as an electrode of the capacitor element C and is electrically connected to the conductive feature 130A and the conductive bonding structure 208 of the chip structure 20. The conductive feature 130A may be used to provide signals and/or power to the capacitor element C and the chip structure 20.

Many variations and/or modifications can be made to embodiments of the disclosure. FIG. 2 is a cross-sectional view of a portion of a package structure, in accordance with some embodiments. A package structure that is similar to that shown in FIG. 1E is formed. In some embodiments, the conductive layer 116B of the capacitor element C is not electrically connected to the conductive layers 116A and 120A, as shown in FIG. 2.

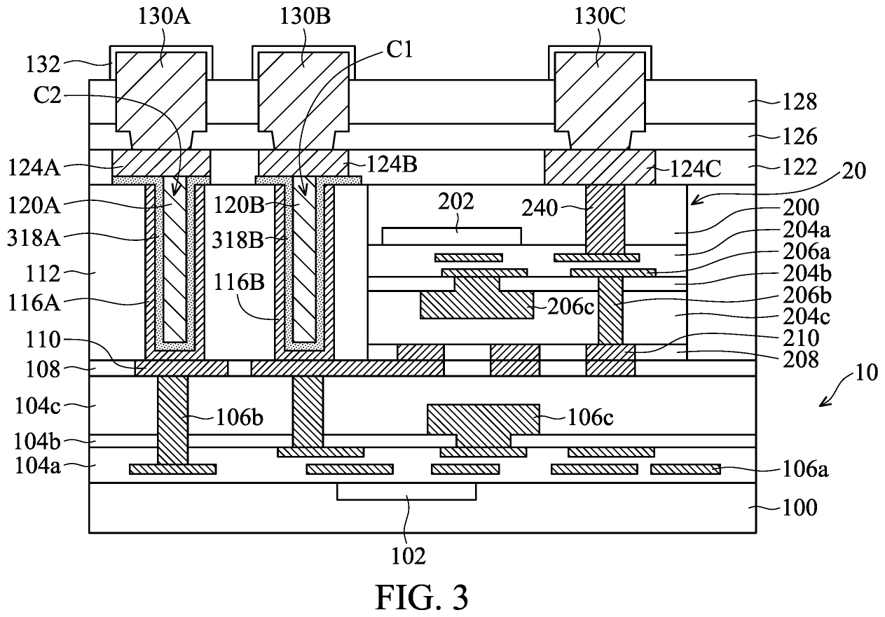

Many variations and/or modifications can be made to embodiments of the disclosure. FIG. 3 is a cross-sectional view of a portion of a package structure, in accordance with some embodiments. A package structure that is similar to that shown in FIG. 2 is formed. In some embodiments, capacitor elements C1 and C2 are formed to fill the openings formed in the insulating layer 112. The material and formation method of the capacitor elements C1 and C2 may be the same as or similar to those of the capacitor element C shown in FIG. 1E. In some embodiments, the capacitor element C1 is electrically connected to the chip structure 20, and the capacitor element C2 is electrically connected to the chip structure 10, as shown in FIG. 3. In some embodiments, the chip structure 10 extends across the opposite edges of the capacitor element C1 and the opposite edges of the capacitor element C2.

In some embodiments, the capacitor element C1 has a capacitor dielectric layer 318B, and the capacitor element C2 has a capacitor dielectric layer 318A. The material and formation method of the capacitor dielectric layers 318A and 318B may be the same as or similar to those of the capacitor dielectric layer 118 of the capacitor element C shown in FIG. 1E. In some embodiments, the capacitor dielectric layers 318A and 318B are patterned from the same capacitor dielectric layer and thus have the same composition. In some embodiments, the capacitor dielectric layers 318A and 318B are formed simultaneously. In some embodiments, the capacitor elements C1 and C2 have the same capacitance. In some other embodiments, the sizes and/or shapes of the capacitor elements C1 and C2 are different from each other. In these cases, the capacitor elements C1 and C2 may have different capacitances.

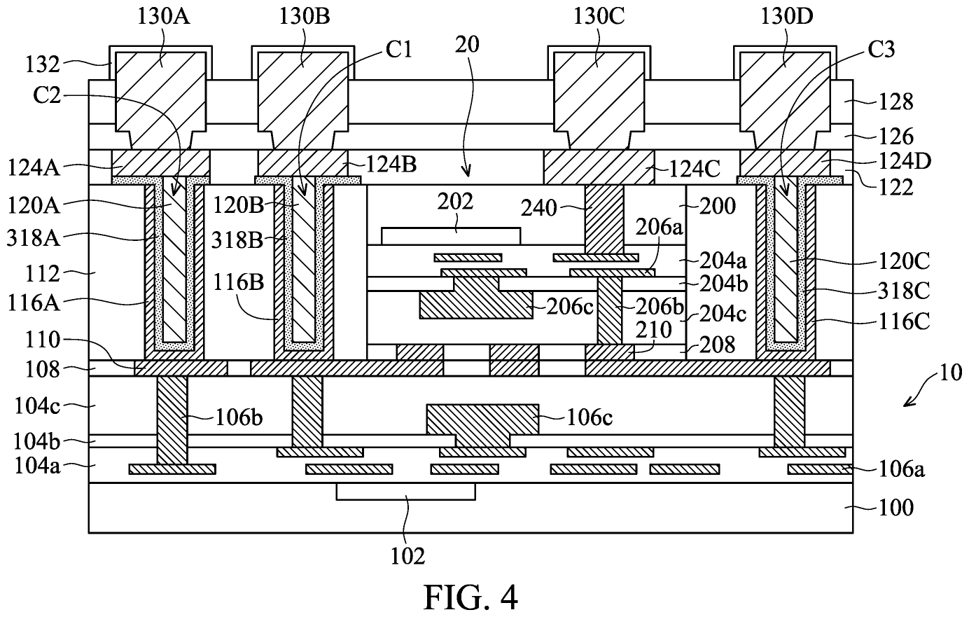

Many variations and/or modifications can be made to embodiments of the disclosure. FIG. 4 is a cross-sectional view of a portion of a package structure, in accordance with some embodiments. A package structure that is similar to that shown in FIG. 3 is formed. In some embodiments, a capacitor element C3 is formed. As shown in FIG. 4, the chip structure 20 is between the capacitor elements C1 and C3. The material and formation method of the capacitor element C3 may be the same as or similar to those of the capacitor element C1. In some embodiments, the capacitor element C3 is electrically connected to the chip structure 20.

In some embodiments, the capacitor element C3 has a capacitor dielectric layer 318C. The material and formation method of the capacitor dielectric layer 318C may be the same as or similar to those of the capacitor dielectric layer 318B of the capacitor element C1. In some embodiments, the capacitor dielectric layers 318A-318C are patterned from the same capacitor dielectric layer and thus have the same composition. In some embodiments, the capacitor dielectric layers 318A-318C are formed simultaneously. In some embodiments, the capacitor elements C1, C2, and C3 have the same capacitance. In some other embodiments, the sizes and/or shapes of the capacitor elements C1-C3 are different from each other. In these cases, two or more of the capacitor elements C1, C2, and C3 may have different capacitances.

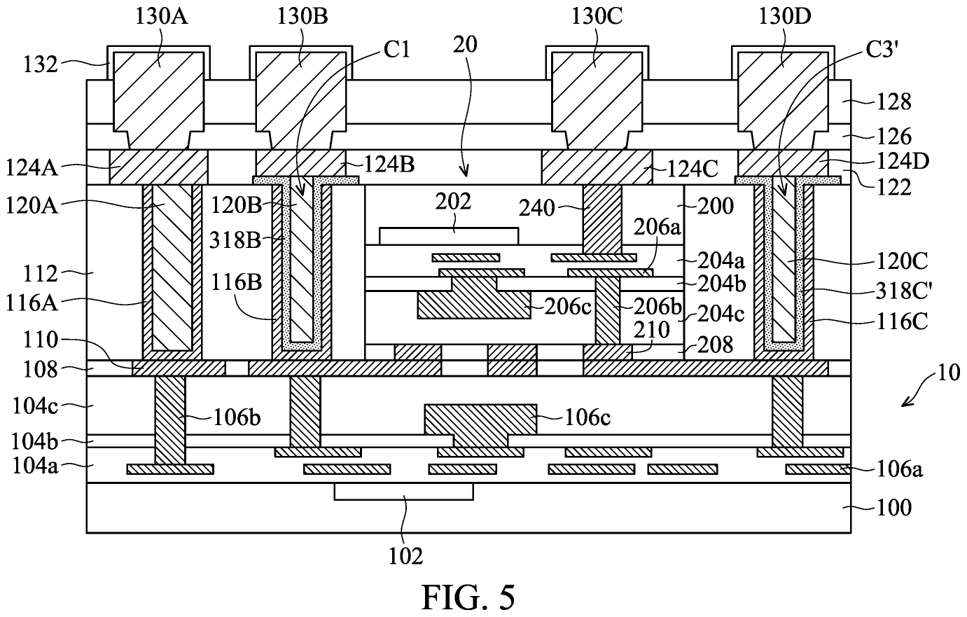

Many variations and/or modifications can be made to embodiments of the disclosure. FIG. 5 is a cross-sectional view of a portion of a package structure, in accordance with some embodiments. A package structure that is similar to that shown in FIG. 1E is formed. In some embodiments, a capacitor element C3′ is formed. As shown in FIG. 5, the chip structure 20 is between the capacitor elements C1 and C3′. The material and formation method of the capacitor element C3′ may be similar to those of the capacitor element C1. In some embodiments, the capacitor element C3′ is electrically connected to the chip structure 20.

In some embodiments, the capacitor element C3′ has a capacitor dielectric layer 318C′. The material and formation method of the capacitor dielectric layer 318C′ may be similar to those of the capacitor dielectric layer 318B of the capacitor element C1. In some embodiments, the capacitor dielectric layers 318B and 318C′ are patterned from different capacitor dielectric layers. In some embodiments, the capacitor dielectric layers 318B and 318C′ have different compositions. In some embodiments, the capacitor elements C1 and C3′ have different capacitances.

Many variations and/or modifications can be made to embodiments of the disclosure. FIGS. 6A-6J are cross-sectional views each showing a portion of a capacitor element of a package structure, in accordance with some embodiments. Each capacitor element formed in the embodiments illustrated in FIGS. 1-5 may be formed to have one of the cross-sectional views shown in FIGS. 6A-6J. By fine-tuning the size, profile, and/or shape of the capacitor elements, the capacitance of the capacitor elements may be tuned accordingly.

For example, a first capacitor element with the cross-sectional view shown in FIG. 6B may have higher capacitance than that of a second capacitor element with the cross-sectional view shown in FIG. 6D. The contact area between the capacitor dielectric layer 118 and the conductive layer 116B of the first capacitor element is larger than the contact area between the capacitor dielectric layer 118 and the conductive layer 116B of the second capacitor element.

In some embodiments, each of the capacitor elements has an outer electrode (i.e., the conductive layer 116B) and an inner electrode (i.e., the conductive layer 120B), as shown in FIGS. 6A-6J. In some embodiments, the inner electrode (i.e., the conductive layer 120B) functions as the grounding electrode. However, embodiments of the disclosure are not limited thereto. In some other embodiments, the outer electrode (i.e., the conductive layer 116B) functions the grounding electrode.

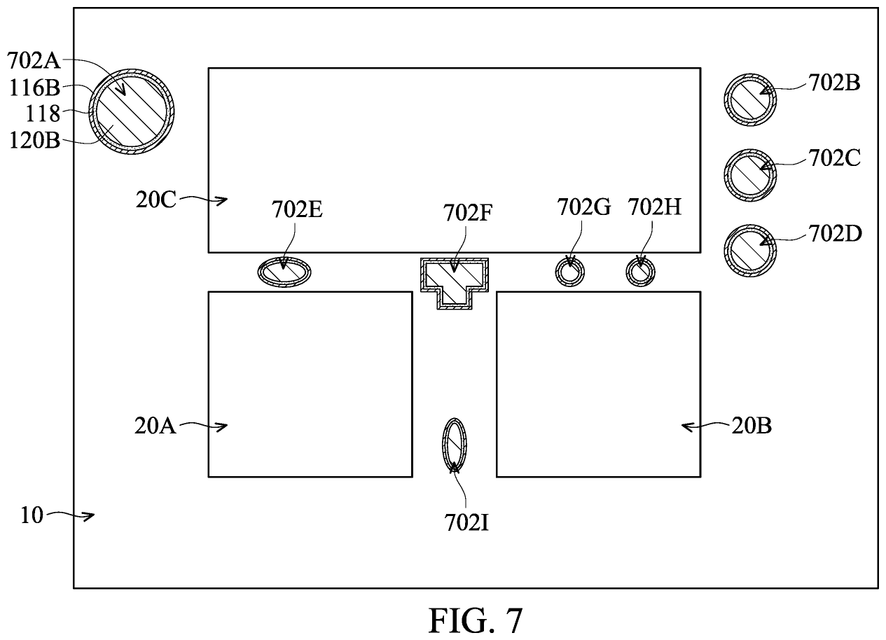

Many variations and/or modifications can be made to embodiments of the disclosure. In some embodiments, there are more than two chip structures are bonded to the chip structure 10 through dielectric-to-dielectric bonding and metal-to-metal bonding. FIG. 7 is a plan view of a portion of a package structure, in accordance with some embodiments. In some embodiments, multiple chip structures 20A, 20B, and 20C are disposed over the chip structure 10. In some embodiments, the chip structures 20A-20C are bonded to the chip structure 10 thereunder through dielectric-to-dielectric bonding and metal-to-metal bonding. In some embodiments, similar to the bonding between the chip structures 10 and 20 illustrated in FIG. 1B, there is no tin-containing solder element or solder bump formed between the lower chip structure and the upper chip structures.

In some embodiments, there are multiple capacitor elements 702A-7021 formed over the chip structure 10. The material and formation method of the capacitor elements 702A-702I may be the same as or similar to the capacitor elements illustrated in FIGS. 1-6. The capacitor elements 702A-7021 may have different shapes, different profiles, and/or different capacitor dielectric layers, so as to provide different capacitances according to the requirements. In some embodiments, the capacitor elements 702A-702D are formed beside the chip structure 20C. In some embodiments, the capacitor elements 702E-7021 are formed on the space between the chip structures that are nearby.

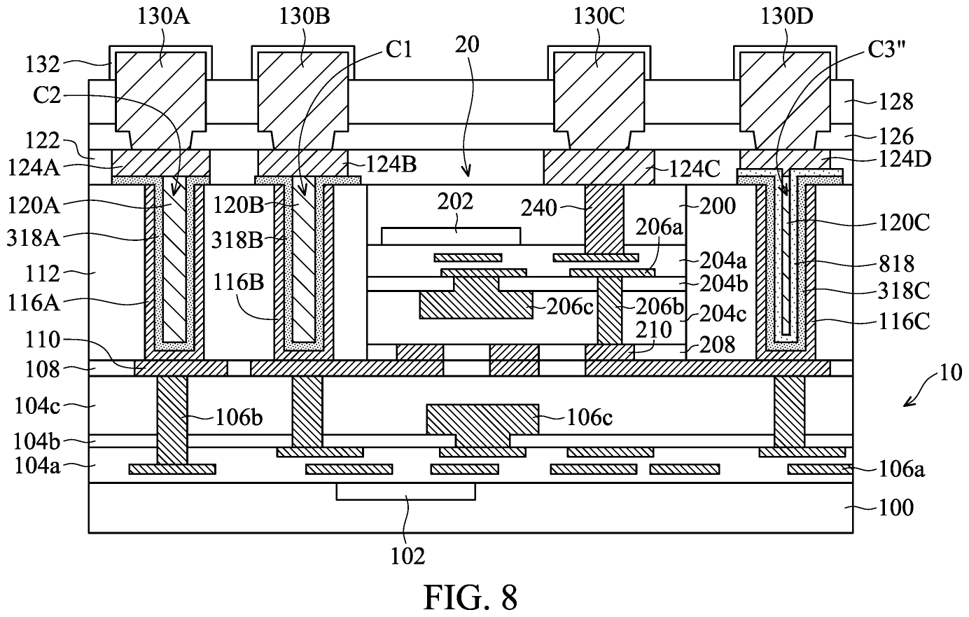

Many variations and/or modifications can be made to embodiments of the disclosure. In some embodiments, one or more capacitor elements have two or more capacitor dielectric layers. FIG. 8 is a cross-sectional view of a portion of a package structure, in accordance with some embodiments. A package structure that is similar to that shown in FIG. 4 is formed. In some embodiments, a capacitor element C3″ is formed. As shown in FIG. 8, the chip structure 20 is between the capacitor elements C1 and C3″. The material and formation method of the capacitor element C3″ may be the same as or similar to those of the capacitor element C1. In some embodiments, the capacitor element C3″ is electrically connected to the chip structure 20.

In some embodiments, the capacitor element C3″ has a first capacitor dielectric layer 318C and a second capacitor dielectric layer 818. The material and formation method of the capacitor dielectric layers 318C and 818 may be the same as or similar to those of the capacitor dielectric layer 318B of the capacitor element C1. In some embodiments, the capacitor dielectric layers 318C and 818 are made of different materials. In some other embodiments, the capacitor dielectric layers 318C and 818 are made of the same material.

In some embodiments, the capacitor elements C1, C2, and C3″ have different capacitances. By forming additional capacitor dielectric layer, the capacitance of the capacitor element may be fine-tuned accordingly.

In some embodiments, the capacitor elements have vertical sidewalls. However, embodiments of the disclosure are not limited thereto. Many variations and/or modifications can be made to embodiments of the disclosure. In some other embodiments, one or more of the capacitor elements have slanted sidewalls. By fine-tuning the slopes of the slanted sidewalls, the capacitance of the capacitor elements may be tuned accordingly.

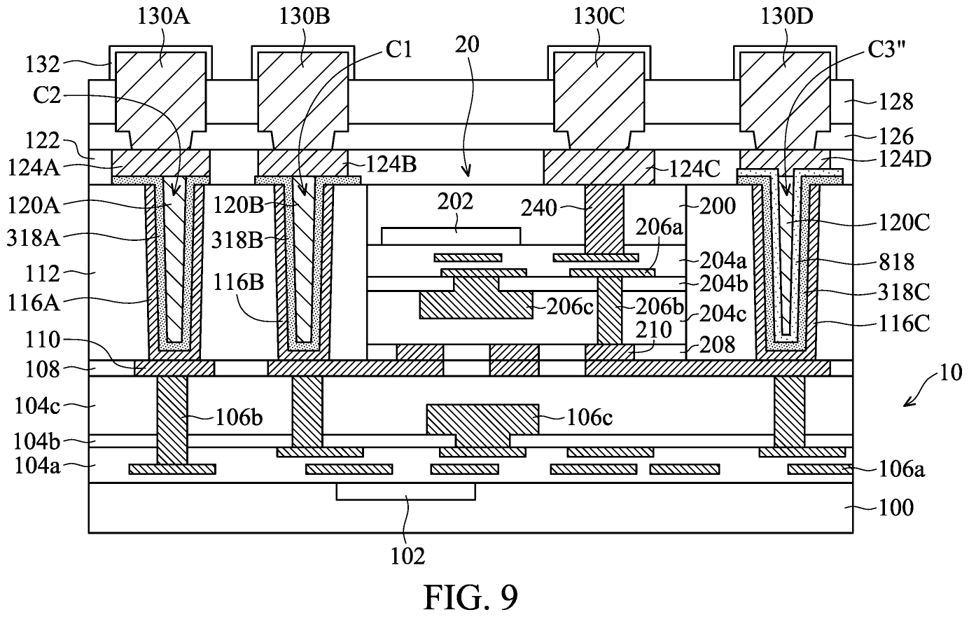

FIG. 9 is a cross-sectional view of a portion of a package structure, in accordance with some embodiments. A package structure that is similar to that shown in FIG. 8 is formed. In some embodiments, the capacitor elements C1, C2, and C3″ have slanted sidewalls. Each of the capacitor elements C1, C2, and C3″ gradually become narrower along a direction towards the chip structure 10.

Many variations and/or modifications can be made to embodiments of the disclosure. In some other embodiments, one or more of the capacitor elements have a curved sidewall.

Embodiments of the disclosure form a package structure that includes a stack of multiple chip structures. The upper chip structure and the lower chip structure are directly bonded to each other through dielectric-to-dielectric bonding and metal-to-metal bonding. One or more embedded capacitor elements are formed over the lower chip structure and spaced apart from the upper chip structure. The shapes, profiles, sizes, and materials of the embedded capacitor elements may be varied so as to provide various capacitance. The capacitance and area of the embedded capacitor elements are tunable, which greatly improves the routing flexibility. The embedded capacitor elements have a shorter interconnection length to the chip structures, which allows for a shorter time delay. The performance and reliability of the package structure are significantly improved, which is suitable for future advanced portable products such as new generation smart phones, flat panels, internet of things, cloud computing devices, and the like.

In accordance with some embodiments, a method for forming a package structure is provided. The method includes receiving a first chip structure, and the first chip structure has multiple conductive bonding structures and a dielectric bonding structure surrounding the conductive bonding structures. Top surfaces of the conductive bonding structures and the dielectric bonding structure are coplanar. The method also includes bonding a second chip structure to the dielectric bonding structure and the conductive bonding structures through dielectric-to-dielectric bonding and metal-to-metal bonding. The method further includes forming an insulating layer over the first chip structure, and the insulating layer laterally surrounds the first chip structure. In addition, the method includes forming a capacitor element laterally spaced apart from the second chip structure, and the insulating layer partially surrounds the capacitor element.

In accordance with some embodiments, a package structure is provided. The package structure includes a first chip structure having multiple conductive bonding structures and a dielectric bonding structure surrounding the conductive bonding structures. Top surfaces of the conductive bonding structures and the dielectric bonding structure are coplanar. The package structure also includes a second chip structure bonded to the dielectric bonding structure and the conductive bonding structures through dielectric-to-dielectric bonding and metal-to-metal bonding. The package structure further includes a capacitor element laterally spaced apart from the second chip structure and an insulating layer laterally surrounding the second chip structure and a portion of the capacitor element.

In accordance with some embodiments, a package structure is provided. The package structure includes a first chip structure and a second chip structure having multiple conductive bonding structures and a dielectric bonding structure surrounding the conductive bonding structures. Top surfaces of the conductive bonding structures and the dielectric bonding structure are coplanar, and the second chip structure is bonded to the first chip structure through dielectric-to-dielectric bonding and metal-to-metal bonding. The package structure also includes a capacitor element laterally spaced apart from the second chip structure. The first chip structure extends across opposite edges of the second chip structure and opposite edges of the capacitor element. The package structure further includes an insulating layer laterally surrounding the second chip structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for forming a package structure, comprising:
receiving a first chip structure, wherein the first chip structure has a plurality of conductive bonding structures and a dielectric bonding structure surrounding the conductive bonding structures, and top surfaces of the conductive bonding structures and the dielectric bonding structure are coplanar;
bonding a second chip structure to the dielectric bonding structure and the conductive bonding structures through dielectric-to-dielectric bonding and metal-to-metal bonding;
forming an insulating layer over the first chip structure, wherein the insulating layer laterally surrounds the first chip structure; and
forming a capacitor element laterally spaced apart from the second chip structure, wherein the insulating layer at least partially surrounds the capacitor element.

2. The method for forming a package structure as claimed in claim 1, further comprising:
forming a first conductive layer, wherein the insulating layer laterally surrounds the first conductive layer;
forming a capacitor dielectric layer over the first conductive layer; and
forming a second conductive layer over the capacitor dielectric layer, wherein the first conductive layer, the capacitor dielectric layer, and the second conductive layer together form the capacitor element.

3. The method for forming a package structure as claimed in claim 2, further comprising:
forming a second capacitor dielectric layer over the capacitor dielectric layer before the second conductive layer is formed.

4. The method for forming a package structure as claimed in claim 3, wherein the capacitor dielectric layer and the second capacitor dielectric layer are made of a same material.

5. The method for forming a package structure as claimed in claim 3, wherein the capacitor dielectric layer and the second capacitor dielectric layer are made of different materials.

6. The method for forming a package structure as claimed in claim 2, wherein a portion of the capacitor dielectric layer is formed over top surfaces of the insulating layer and the first conductive layer.

7. The method for forming a package structure as claimed in claim 2, further comprising:
forming a third conductive layer, wherein the insulating layer laterally surrounds the third conductive layer; and
forming a fourth conductive layer over the third conductive layer.

8. The method for forming a package structure as claimed in claim 7, wherein the third conductive layer and the first conductive layer are formed simultaneously, and the fourth conductive layer and the second conductive layer are formed simultaneously.

9. The method for forming a package structure as claimed in claim 1, further comprising:
forming a second capacitor element laterally spaced apart from the second chip structure, wherein the insulating layer at least partially surrounds the second capacitor element.

10. The method for forming a package structure as claimed in claim 1, further comprising:
disposing a third chip structure over the first chip structure, wherein the capacitor element is between the second chip structure and the third chip structure.

11. A package structure, comprising:
a first chip structure having a plurality of conductive bonding structures and a dielectric bonding structure surrounding the conductive bonding structures, wherein top surfaces of the conductive bonding structures and the dielectric bonding structure are coplanar;
a second chip structure bonded to the dielectric bonding structure and the conductive bonding structures through dielectric-to-dielectric bonding and metal-to-metal bonding;
a capacitor element laterally spaced apart from the second chip structure; and
an insulating layer laterally surrounding the second chip structure and at least a portion of the capacitor element.

12. The package structure as claimed in claim 11, wherein the capacitor element comprises:
a first conductive layer extending along interior sidewalls of the insulating layer;
a capacitor dielectric layer over the first conductive layer; and
a second conductive layer over the capacitor dielectric layer.

13. The package structure as claimed in claim 12, wherein the capacitor dielectric layer covers a top surface of the first conductive layer and a top surface of the insulating layer.

14. The package structure as claimed in claim 11, wherein an outermost edge of the insulating layer is coplanar with an outermost edge of the first chip structure.

15. The package structure as claimed in claim 11, wherein there is no tin-containing solder element formed between the first chip structure and the second chip structure.

16. A package structure, comprising:
a first chip structure;
a second chip structure having a plurality of conductive bonding structures and a dielectric bonding structure surrounding the conductive bonding structures, wherein top surfaces of the conductive bonding structures and the dielectric bonding structure are coplanar, and the second chip structure is bonded to the first chip structure through dielectric-to-dielectric bonding and metal-to-metal bonding;
a capacitor element laterally spaced apart from the second chip structure, wherein the first chip structure extends across opposite edges of the second chip structure and opposite edges of the capacitor element; and
an insulating layer laterally surrounding the second chip structure.

17. The package structure as claimed in claim 16, wherein top surfaces of the insulating layer and the second chip structure are coplanar.

18. The package structure as claimed in claim 17, wherein the capacitor element has a capacitor dielectric layer, the capacitor dielectric layer covers the top surface of the insulating layer, and a bottommost surface of the capacitor dielectric layer is between the top surface of the insulating layer and a bottom surface of the insulating layer.

19. The package structure as claimed in claim 16, further comprising:
a second capacitor element laterally spaced apart from the second chip structure, wherein the first chip structure extends across opposite edges of the second capacitor element.

20. The package structure as claimed in claim 19, wherein:
the capacitor element has a first conductive layer and a first capacitor dielectric layer over the first conductive layer,
the second capacitor element has a second conductive layer and a second capacitor dielectric layer over the second conductive layer, and
a first contact area between the first conductive layer and the first capacitor dielectric layer is larger than a second contact area between the second conductive layer and the second capacitor dielectric layer.
